(19) United States
(12) Patent Application Publication
(10) Pub. No.: US 2026/0082993 A1
(43) Pub. Date: Mar. 19, 2026

(54) SEMICONDUCTOR PACKAGE AND ELECTRONIC DEVICE

(71) Applicant: SONY SEMICONDUCTOR SOLUTIONS CORPORATION, KANAGAWA (JP)

(72) Inventors: TOSHIKI KOYAMA, KANAGAWA (JP); HARUMI MIYAKI, KANAGAWA (JP); SATOSHI KUMON, KANAGAWA (JP)

(21) Appl. No.: 19/110,004

(22) PCT Filed: Jul. 20, 2023
(86) PCT No.: PCT/JP2023/026524

§ 371 Date: Mar. 7, 2025

(30) Foreign Application Priority Data
Sep. 14, 2022 (JP) 2022-145724

(51) Int. Cl. H10W 76/63; H10F 77/50

(52) U.S. Cl. CPC H10W 76/63; H10F 77/50; H10W 90/734

(57) ABSTRACT

To suppress flowing out of an adhesive to the outside of a prescribed region in a semiconductor package in which a substrate is bonded to a support by the adhesive. A semiconductor package includes a substrate, a semiconductor chip, a support, and a first adhesive. In this semiconductor package, the semiconductor chip is placed on a substrate flat surface of the substrate and electrically connected to the substrate. Further, in the semiconductor package, a part of the first adhesive flows into a gap between the substrate flat surface and the semiconductor chip, and adheres the substrate to the support.

### TECHNICAL FIELD

The present technology relates to a semiconductor package. Specifically, the present technology relates to a semiconductor package for bonding a substrate to a support, and an electronic device.

### BACKGROUND ART

Conventionally, an adhesive has been often used for sealing a semiconductor chip in a semiconductor package. For example, a semiconductor package has been proposed in which a semiconductor chip is mounted on a substrate by wire bonding, and a wire and a bonding terminal are sealed with an adhesive when the substrate is bonded to a support (see, for example, Patent Document 1.).

### CITATION LIST

### Patent Document

Patent Document 1: Japanese Patent Application Laid-Open No. 2012-095177

### SUMMARY OF THE INVENTION

### Problems to be Solved by the Invention

In the above-described conventional technique, the wire and the bonding terminal are sealed with the adhesive to prevent moisture from entering a wire connection portion. However, when the semiconductor chip is inclined at the time of bonding, the adhesive may flow out to the outside of a prescribed region.

The present technology has been made in view of such a situation, and an object of the present technology is to suppress flowing out of an adhesive to the outside of the prescribed region in a semiconductor package in which a substrate is bonded to a support by an adhesive.

### Solutions to Problems

The present technology has been made to solve the above-described problems, and a first aspect thereof is a semiconductor package including: a substrate; a semiconductor chip placed on a substrate flat surface of the substrate and electrically connected to the substrate; a support; and a first adhesive partially flowing into a gap between the substrate flat surface and the semiconductor chip to bond the substrate to the support. This brings about an effect of suppressing flowing out of the adhesive to the outside of the prescribed region.

In addition, in the first aspect, a trench may be formed on the substrate flat surface. This brings about an effect that the adhesive flows into the trench.

In addition, in the first aspect, the trench may be formed on a base material of the substrate. This brings about an effect that a deep trench is formed.

In addition, in the first aspect, the trench may be formed by a solder resist. This brings about an effect that a trench having a complicated shape and high accuracy can be formed by photolithography.

In addition, in the first aspect, the trench may include a conductor pattern. This brings about an effect that a trench having a complicated shape and high accuracy can be formed by photolithography.

In addition, in the first aspect, the trench may be formed by silk printing. This brings about an effect that a trench is formed by a simple method.

In addition, in the first aspect, the semiconductor package may further include a die bond resin that contains a filler and bonds the semiconductor chip to the substrate flat surface. This brings about an effect of suppressing the inclination of the semiconductor chip.

In addition, in the first aspect, the semiconductor package may further include: a second adhesive; and glass, in which one of both surfaces of the support is bonded to the substrate with the first adhesive, and the other surface is bonded to the glass with the second adhesive. This brings about an effect that the glass is fixed.

In addition, in the first aspect, the semiconductor package may further include a silicone resin, in which the support has an opening, a projection protruding toward the semiconductor chip is formed around the opening on the one of both surfaces of the support, and the silicone resin is provided between the projection and the semiconductor chip. This brings about an effect of suppressing flowing out of the adhesive onto the semiconductor chip.

Further, in the first aspect, a first slit may be formed on the one of both surfaces of the support. This brings about an effect of preventing flowing out of the first adhesive.

Furthermore, in the first aspect, the first slit may include: a plurality of first slit portions parallel or perpendicular to a side of the support; and a plurality of second slit portions formed in an oblique direction. This brings about an effect of preventing flowing out of the first adhesive.

In addition, in the first aspect, a second slit may be formed on the other of both surfaces of the support. This brings about an effect of suppressing flowing out of the second adhesive.

Further, in the first aspect, a through hole may be formed in the support. This brings about an effect of suppressing flowing out of the first and second adhesives.

Furthermore, a second aspect of the present technology is an electronic device including: a substrate; a semiconductor chip placed on a substrate flat surface of the substrate and electrically connected to the substrate; a support; a first adhesive partially flowing into a gap between the substrate flat surface and the semiconductor chip to bond the substrate to the support; and an optical section that guides light to the semiconductor chip. This brings about an effect of suppressing flowing out of the adhesive to the outside of the prescribed region in the electronic device.

### BRIEF DESCRIPTION OF DRAWINGS

FIG. 1 is a block diagram illustrating a configuration example of an electronic device according to a first embodiment of the present technology.

FIG. 2 is an example of a cross-sectional view of a semiconductor package according to the first embodiment of the present technology.

FIG. 3 is a view for explaining an effect of providing a trench of the semiconductor package according to the first embodiment of the present technology.

FIG. 4 is an example of a top view and a cross-sectional view of a substrate in which a through hole is formed according to the first embodiment of the present technology.

FIG. 5 is an example of a top view and a cross-sectional view of a substrate on which a trench is formed according to the first embodiment of the present technology.

FIG. 6 is an example of a top view and a cross-sectional view of the substrate coated with a die bond resin according to the first embodiment of the present technology.

FIG. 7 is an example of a top view and a cross-sectional view of a semiconductor package in which a sensor chip is die-bonded according to the first embodiment of the present technology.

FIG. 8 is an example of a top view and a cross-sectional view of the semiconductor package on which wire bonding is performed according to the first embodiment of the present technology.

FIG. 9 is an example of a bottom view and a cross-sectional view of a support to which an adhesive is applied according to the first embodiment of the present technology.

FIG. 10 is an example of a top view and a cross-sectional view of the semiconductor package on which a support is placed according to the first embodiment of the present technology.

FIG. 11 is an example of a top view and a cross-sectional view of the semiconductor package in which the substrate is brought into pressure contact according to the first embodiment of the present technology.

FIG. 12 is an example of a top view and a cross-sectional view of the semiconductor package to which glass is bonded according to the first embodiment of the present technology.

FIG. 13 is a flowchart illustrating an example of a method for manufacturing the semiconductor package according to the first embodiment of the present technology.

FIG. 14 is a view for explaining a method for forming the trench with a solder resist according to the first embodiment of the present technology.

FIG. 15 is a view for explaining a method for forming the trench by a conductor pattern according to the first embodiment of the present technology.

FIG. 16 is a view for explaining a method for forming the trench by grinding the substrate according to the first embodiment of the present technology.

FIG. 17 is an example of a cross-sectional view of a semiconductor package according to a second embodiment of the present technology.

FIG. 18 is an example of a top view and a cross-sectional view of a substrate in which a through hole is formed according to the second embodiment of the present technology.

FIG. 19 is an example of a top view and a cross-sectional view of the substrate coated with a die bond resin according to the second embodiment of the present technology.

FIG. 20 is an example of a top view and a cross-sectional view of a semiconductor package in which a sensor chip is die-bonded according to the second embodiment of the present technology.

FIG. 21 is an example of a top view and a cross-sectional view of a substrate according to a third embodiment of the present technology.

FIG. 22 is an example of a top view and a cross-sectional view of the semiconductor package according to the third embodiment of the present technology.

FIG. 23 is an example of a cross-sectional view and an enlarged view of a semiconductor package according to a fourth embodiment of the present technology.

FIG. 24 is an example of a bottom view and a cross-sectional view of a support to which an adhesive is applied according to the fourth embodiment of the present technology.

FIG. 25 is an example of a bottom view and a cross-sectional view of the support coated with a silicone resin according to the fourth embodiment of the present technology.

FIG. 26 is a view illustrating an example of a shape of a projection according to the fourth embodiment of the present technology.

FIG. 27 is a view for explaining a method for curing a silicone resin according to the fourth embodiment of the present technology.

FIG. 28 is an example of a top view and a bottom view of a support according to a fifth embodiment of the present technology.

FIG. 29 is an example of a bottom view and a cross-sectional view of a support to which an adhesive is applied according to the fifth embodiment of the present technology.

FIG. 30 is an example of a top view and a cross-sectional view of a semiconductor package on which a support is placed according to the fifth embodiment of the present technology.

FIG. 31 is an example of a top view and a cross-sectional view of the semiconductor package in which the substrate is brought into pressure contact according to the fifth embodiment of the present technology.

FIG. 32 is an example of a top view and a cross-sectional view of the semiconductor package to which glass is bonded according to the fifth embodiment of the present technology.

FIG. 33 is a plan view illustrating another pattern of a slit in a lower surface of the support according to the fifth embodiment of the present technology.

FIG. 34 is a plan view illustrating a pattern of trenches on an upper surface of the substrate according to the fifth embodiment of the present technology.

FIG. 35 is an example of a top view and a bottom view of a support in a modification of the fifth embodiment of the present technology.

FIG. 36 is an example of a cross-sectional view of a semiconductor package 200 according to a modification of the fifth embodiment of the present technology.

FIG. 37 is a block diagram illustrating a schematic configuration example of a vehicle control system.

FIG. 38 is an explanatory view illustrating an example of an installation position of an imaging section.

### MODE FOR CARRYING OUT THE INVENTION

In the following, modes for carrying out the present technology (hereinafter referred to as embodiments) will be described.

The explanation will be made in the following order.
1. First Embodiment (Example in which Trench is Formed in Substrate)
2. Second Embodiment (Example in which Die Bond Resin Containing Filler is Used)
3. Third Embodiment (Example in which Trench is Formed in Substrate and Die Bond Resin Containing Filler is Used)
4. Fourth Embodiment (Example in which Trench is Formed in Substrate and Protrusion is Formed in Support)
5. Fifth Embodiment (Example in which Trench is Formed in Substrate and Slit is Formed in Support)
6. Example of Application to Mobile Body

### 1. First Embodiment

### [Configuration Example of Electronic Device]

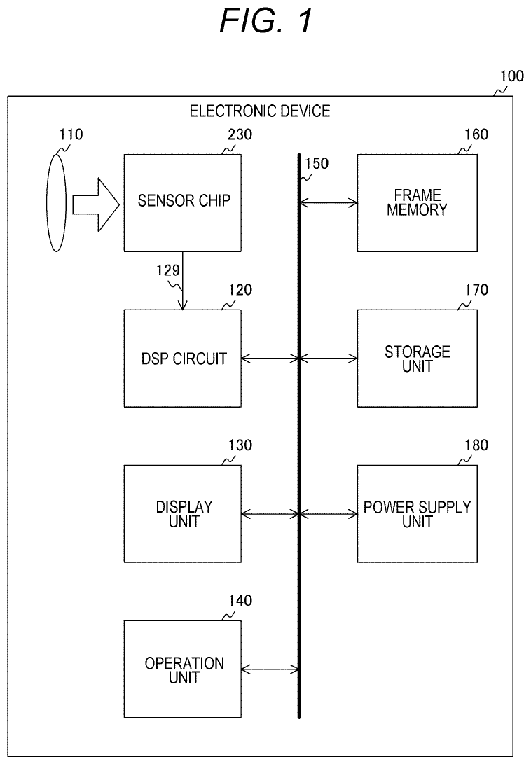

FIG. 1 is a block diagram illustrating a configuration example of an electronic device 100 according to a first embodiment of the present technology. The electronic device 100 is a device for capturing image data and includes an optical section 110, a sensor chip 230, and a digital signal processing (DSP) circuit 120. The electronic device 100 further includes a display section 130, an operation section 140, a bus 150, a frame memory 160, a storage section 170, and a power supply section 180. The electronic device 100 is assumed to be, for example, a digital camera such as a digital still camera, a smartphone, a personal computer, an in-vehicle camera, or the like.

The optical section 110 collects light from a subject and guides the light to the sensor chip 230. The sensor chip 230 generates image data by photoelectric conversion in synchronization with a vertical synchronization signal. Here, the vertical synchronization signal is a periodic signal of a predetermined frequency indicating imaging timing. The sensor chip 230 supplies the generated image data to the DSP circuit 120. The sensor chip 230 is, for example, a CMOS image sensor (CIS).

The DSP circuit 120 performs predetermined signal processing on the image data from the sensor chip 230. The DSP circuit 120 outputs the processed image data to the frame memory 160 or the like via the bus 150.

The display section 130 displays the image data. The display section 130 is assumed to be a liquid crystal panel or an organic electro luminescence (EL) panel, for example. The operation section 140 generates an operation signal in accordance with a user's operation.

The bus 150 is a common path through which the optical section 110, the sensor chip 230, the DSP circuit 120, the display section 130, the operation section 140, the frame memory 160, the storage section 170, and the power supply section 180 exchange data with each other.

The frame memory 160 holds image data. The storage section 170 stores various kinds of data such as image data. The power supply section 180 supplies power to the sensor chip 230, the DSP circuit 120, the display section 130, and the like.

In the above configuration, for example, the sensor chip 230 is mounted in a semiconductor package.

### [Configuration Example of Semiconductor Package]

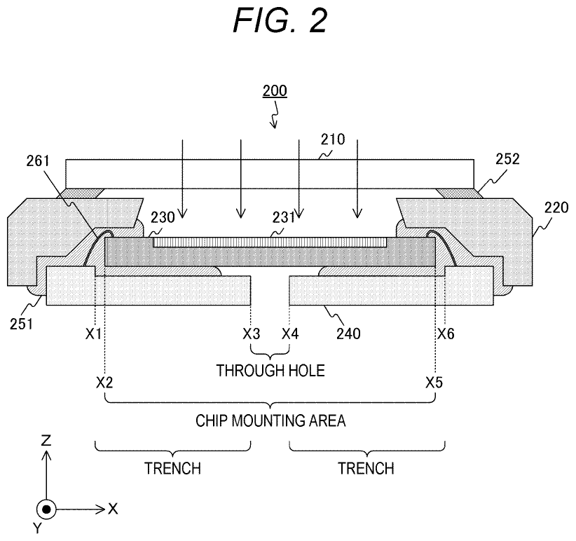

FIG. 2 is an example of a cross-sectional view of a semiconductor package 200 according to the first embodiment of the present technology. The semiconductor package 200 includes glass 210, a support 220, a sensor chip 230, and a substrate 240. In the drawing, an arrow indicates an incident direction of incident light from the optical section 110 (not illustrated).

Hereinafter, an axis parallel to an optical axis is defined as a Z-axis, and a predetermined axis perpendicular to the Z-axis is defined as an X-axis. An axis perpendicular to the X-axis and the Z-axis is defined as a Y-axis. Further, a direction toward the optical section 110 is defined as an upward direction. The drawing is a cross-sectional view when viewed from a Y-axis direction.

The sensor chip 230 is placed on a chip mounting area on the upper surface of the substrate 240 and bonded by a die bond resin (not illustrated). In addition, the sensor chip 230 is electrically connected to the substrate 240 by a wire 261 such as Au (gold). In the drawing, coordinates X2 and X5 indicate coordinates of the left end and the right end of the chip mounting area. Furthermore, a light receiving section 231 in which a plurality of pixels is arranged is provided on an upper surface (in other words, the light receiving surface) of the sensor chip 230. Note that the sensor chip 230 is an example of a semiconductor chip described in the claims.

In addition, a through hole penetrating the substrate 240 is formed in a central portion of the substrate flat surface of the substrate 240. In the drawing, coordinates X3 and X4 indicate coordinates of the left end and the right end of the through hole. By forming the through hole, gas is discharged from the through hole when the substrate 240 is bonded, and generation of voids can be prevented.

Then, on the upper surface of the substrate 240, a trench is formed in a path from the outside of the chip mounting area to the through hole. In the drawing, trenches are formed in a path from the coordinate X1 to the coordinate X3 and a path from the coordinate X4 to a coordinate X6. These trenches cause a step at the coordinates X1 and X6.

The support 220 is a frame-shaped member used to support the glass 210. The glass 210 is bonded to the upper surface of the support 220 with an adhesive 252. In addition, an adhesive 251 adheres the substrate 240 on which the sensor chip 230 is mounted to the support 220 while sealing the wire 261 and the periphery thereof. Note that the adhesive 251 is an example of a first adhesive described in the claims, and the adhesive 252 is an example of a second adhesive described in the claims.

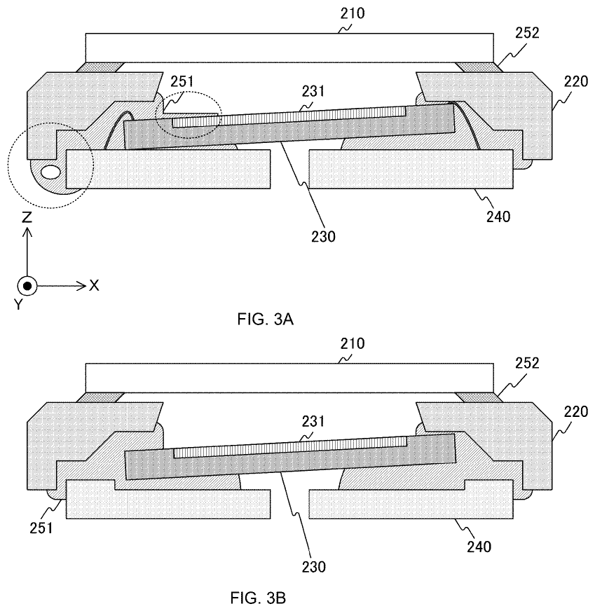

FIG. 3 is a view for explaining an effect of providing the trench of the semiconductor package according to the first embodiment of the present technology.

Here, a configuration in which no trench is formed on the upper surface of the substrate 240 is assumed as a comparative example. In the drawing, a shows a cross-sectional view of a comparative example. As described above, the substrate 240 on which the sensor chip 230 is mounted is bonded to the support 220 by the adhesive 251. During this bonding, the sensor chip 230 may be inclined with respect to the substrate flat surface due to variations in facility accuracy, flatness of the substrate 240, resin physical properties, and the like. When the sensor chip 230 is inclined, a gap between the sensor chip 230 and the substrate 240 also varies. If this gap is too narrow, the adhesive 251 may flow out to the outside of a prescribed region (the outside of the semiconductor package 200 and the light receiving section 231) in the comparative example. Alternatively, voids may be generated in the adhesive 251. A portion surrounded by a dotted line of a in the drawing indicates a portion where the adhesive 251 has flowed out to the outside of the prescribed region or a portion where voids have been generated.

On the other hand, in a case where a trench is formed on the upper surface of the substrate 240 as exemplified in b in the drawing, even if the sensor chip 230 is inclined at the time of bonding, a sufficient gap can be stably secured between the sensor chip 230 and the substrate 240. Since a part of the adhesive 251 easily flows into this gap, it is possible to suppress flowing out of the adhesive out to the outside of the prescribed region and the generation of voids. By preventing flowing out, the small semiconductor package 200 and the electronic device 100 can be easily realized.

### [Method for Manufacturing Semiconductor Package]

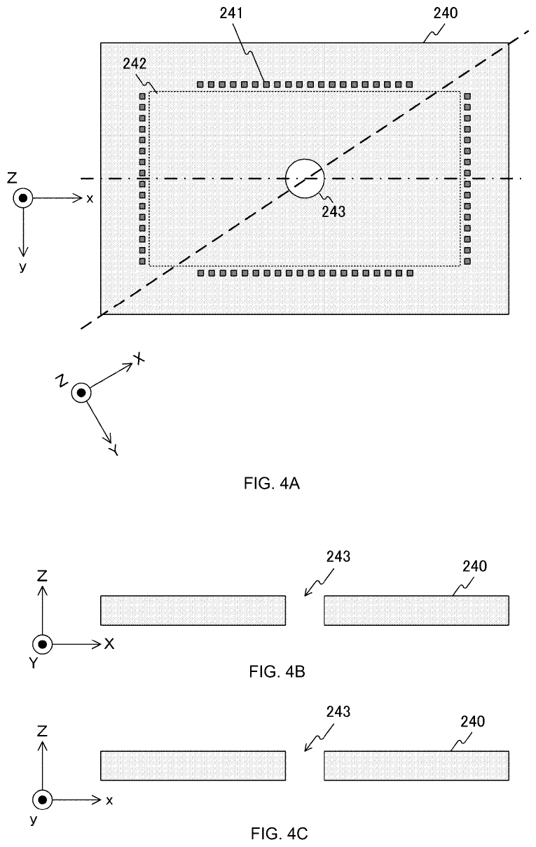

Next, a method for manufacturing the semiconductor package 200 will be described with reference to FIGS. 4 to 12.

FIG. 4 is an example of a top view and a cross-sectional view of the substrate 240 in which the through hole is formed according to the first embodiment of the present technology. In the drawing, a shows a top view of the substrate 240, and b shows a cross-sectional view of the substrate 240 when cut along a rough dotted line of a in the drawing. In the drawing, c illustrates a cross-sectional view of the substrate 240 when cut along the one-dot chain line of a in the drawing.

Further, the substrate 240 is rectangular when viewed from above, and the rough dotted line of a in FIG. 4 is drawn along a diagonal line of the rectangle. An axis parallel to the diagonal corresponds to the X-axis in FIG. 1. One-dot chain line of a in FIG. 4 is drawn in parallel to a side of the substrate 240, and an axis parallel to this side is defined as an x-axis. An axis perpendicular to the x axis and the Z axis is defined as a y axis. The similarity applies to the subsequent drawings.

As exemplified in a in the drawing, a through hole 243 is formed at the center of the upper surface of the substrate 240. In addition, a predetermined number of terminals 241 are arranged along the periphery of the chip mounting area 242 surrounded by a fine dotted line.

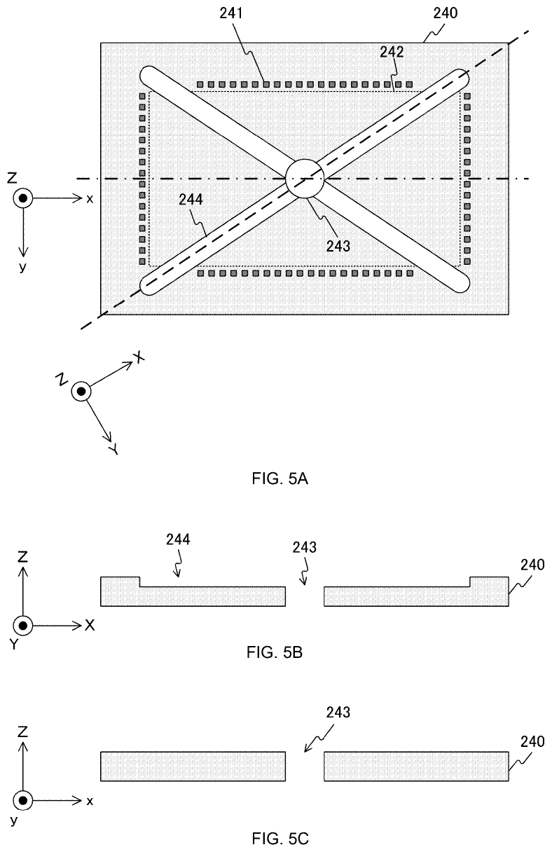

FIG. 5 is an example of a top view and a cross-sectional view of a substrate 240 in which a trench 244 is formed according to the first embodiment of the present technology. In the drawing, a shows a top view of the substrate 240, and b shows a cross-sectional view of the substrate 240 when cut along a rough dotted line of a in the drawing. In the drawing, c illustrates a cross-sectional view of the substrate 240 when cut along the one-dot chain line of a in the drawing.

As exemplified in a of the figure, after the formation of the through hole 243, the trench 244 is formed along the diagonal line in the path from the outside of the chip mounting area 242 to the through hole 243. Details of a method for forming the trench 244 will be described later. Note that, although the trench 244 is formed so as to have a cross shape along the diagonal line, the shape of the trench 244 is not limited to the shape shown in a in the drawing as long as a sufficient gap can be secured.

As exemplified in b of the figure, a step is generated by the trench 244 in the XZ cross section. On the other hand, as exemplified in c in the drawing, since there is no trench 244 in the xZ cross section, no step is generated.

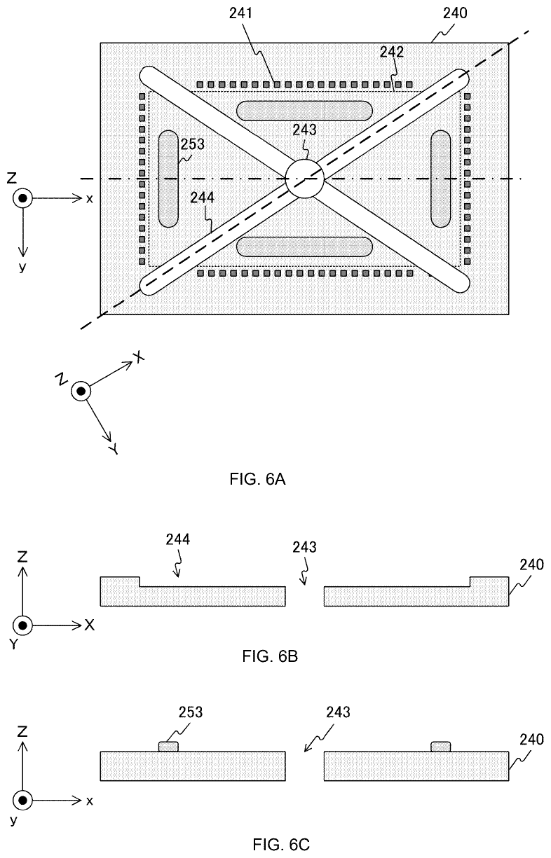

FIG. 6 is an example of a top view and a cross-sectional view of the substrate 240 coated with a die bond resin 253 according to the first embodiment of the present technology. In the drawing, a shows a top view of the substrate 240, and b shows a cross-sectional view of the substrate 240 when cut along a rough dotted line of a in the drawing. In the drawing, c illustrates a cross-sectional view of the substrate 240 when cut along the one-dot chain line of a in the drawing.

As exemplified in a in the drawing, the die bond resin 253 is applied to the inside of the chip mounting area 242 after the formation of the trench 244. The die bond resin 253 does not contain a filler to be described later.

As exemplified in a, b, and c in the figure, the die bond resin 253 is applied while avoiding the trench 244.

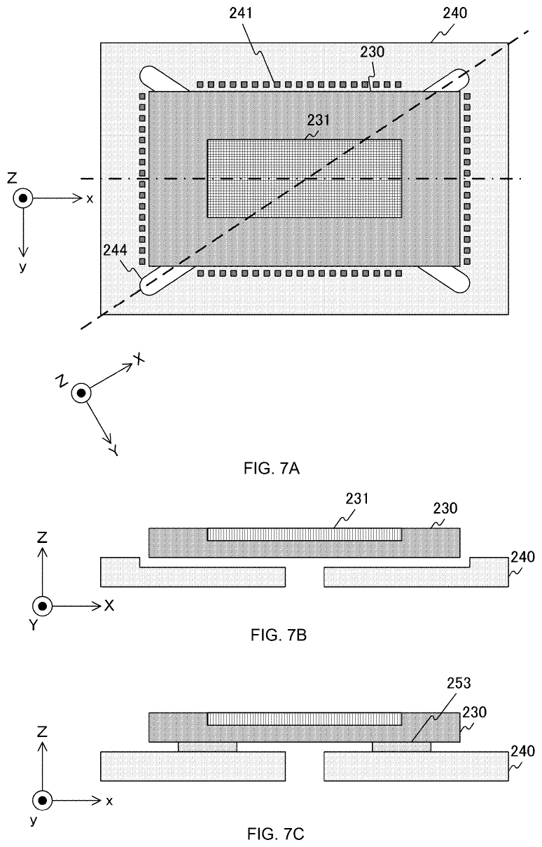

FIG. 7 is an example of a top view and a cross-sectional view of the semiconductor package 200 to which the sensor chip 230 is die-bonded according to the first embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in c in the drawing, after the die bond resin 253 is applied, the sensor chip 230 is placed on the chip mounting area 242 and die-bonded.

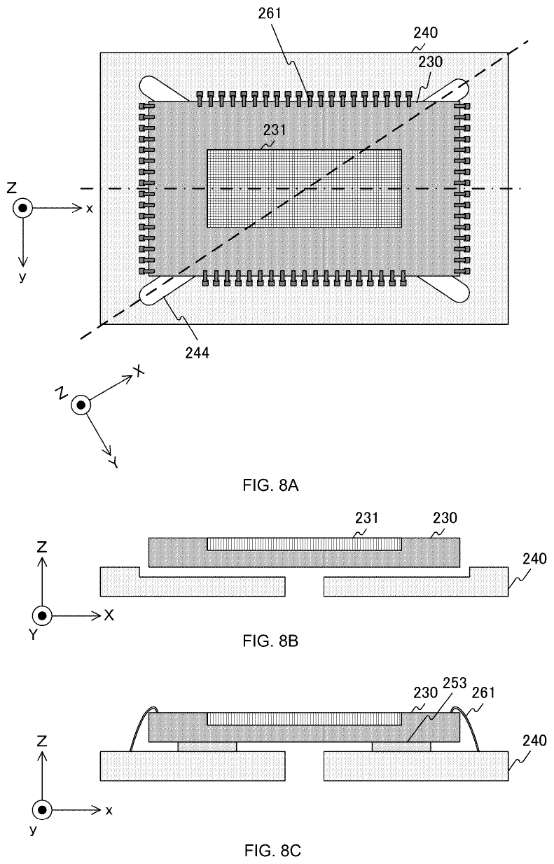

FIG. 8 is an example of a top view and a cross-sectional view of the semiconductor package 200 on which wire bonding is performed according to the first embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a and c in the drawing, the sensor chip 230 and the substrate 240 are electrically connected by the wire 261. That is, wire bonding is performed. The substrate 240 on which the sensor chip 230 is mounted by wire bonding as described above is hereinafter referred to as a “substrate with a sensor chip”.

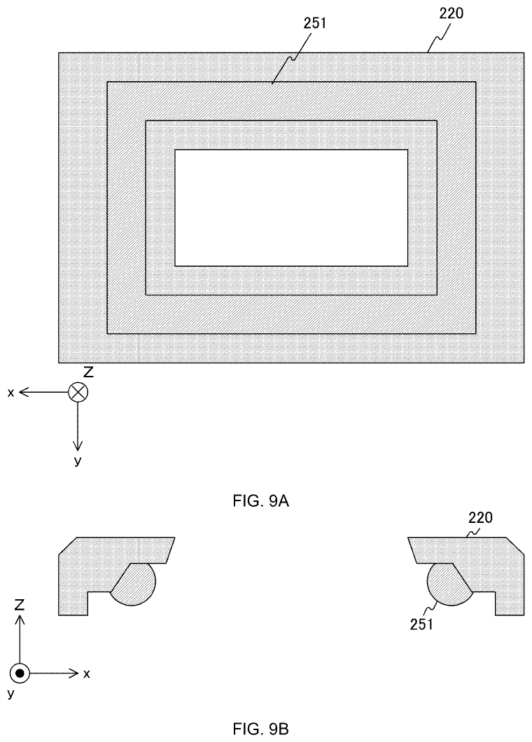

FIG. 9 is an example of a bottom view and a cross-sectional view of the support 220 to which the adhesive 251 is applied according to the first embodiment of the present technology. In the drawing, a shows a bottom view of the support 220, and b shows a cross-sectional view of the support 220.

As exemplified in a in the drawing, the support 220 is a frame-shaped member having a rectangular opening. The adhesive 251 is applied so as to surround the opening. This process is performed by vertically inverting the support 220. Furthermore, the process shown in FIG. 9 may be executed in parallel with the processes shown in FIGS. 4 to 8, or may be executed after FIG. 8.

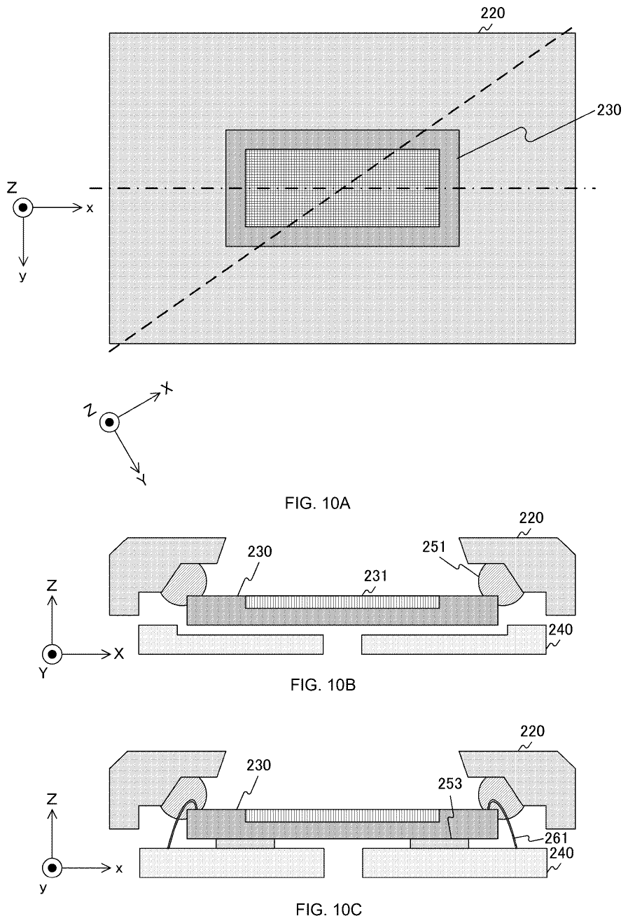

FIG. 10 is an example of a top view and a cross-sectional view of the semiconductor package 200 on which the support 220 is placed according to the first embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a, b, and c in the drawing, after the adhesive 251 is applied, the support 220 is placed on the substrate 240 with a sensor chip. Then, the support 220 is aligned such that the light receiving section 231 of the sensor chip 230 is positioned in the opening of the support 220.

Note that, in this drawing, for convenience of description, portions having the same pattern are generated, but the same material is not necessarily used for portions having the same pattern. For example, although the support 220 and the die bond resin 253 in c in the drawing have the same pattern, the materials used are different. The similarity applies to the following drawings.

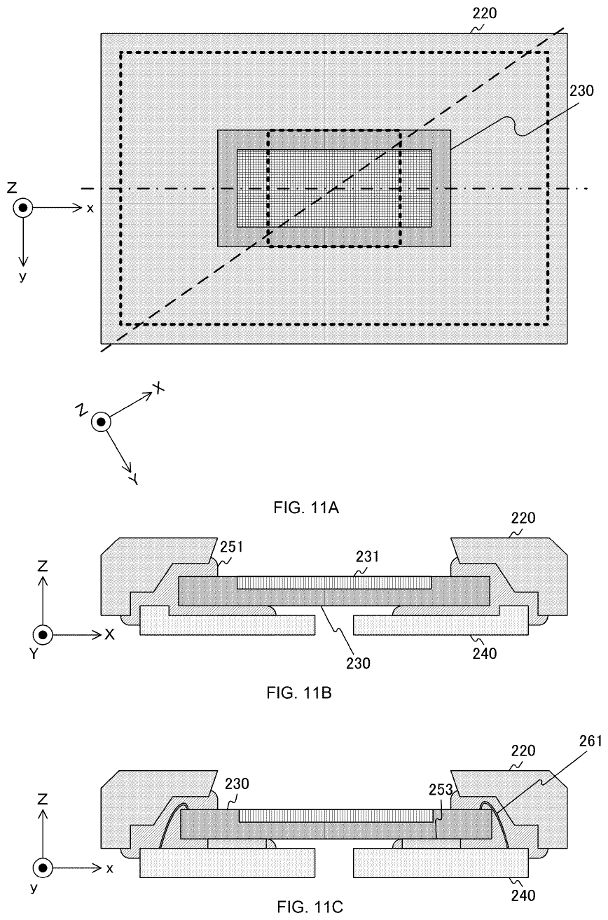

FIG. 11 is an example of a top view and a cross-sectional view of the semiconductor package 200 in which the substrate 240 is brought into pressure contact according to the first embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a, b, and c in the drawing, the substrate 240 with a sensor chip is brought into pressure contact with the support 220 after the alignment. At this time, since the adhesive 251 which flows by being crushed also flows into the trench 244, flowing out of the adhesive 251 to the outside of the semiconductor package 200 or an unnecessary portion such as the light receiving section 231 is suppressed. A thick dotted line of a in the drawing indicates the boundary of the spread area of the adhesive 251. As exemplified particularly by the inner dotted line, a part of the adhesive 251 also flows into the gap between the sensor chip 230 and the substrate 240.

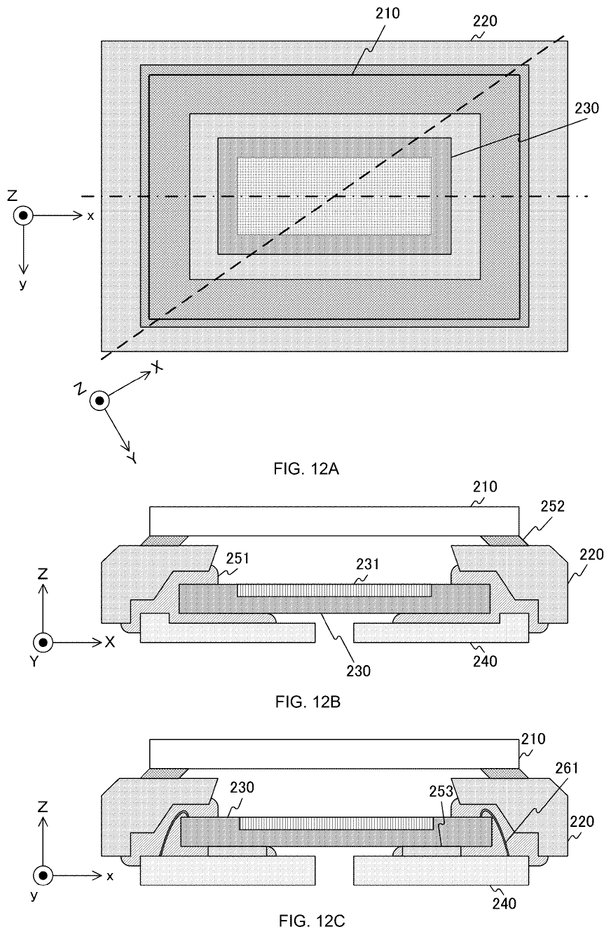

FIG. 12 is an example of a top view and a cross-sectional view of the semiconductor package 200 to which the glass 210 is bonded according to the first embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a, b, and c in the drawing, after the substrate 240 with a sensor chip is brought into pressure contact, the adhesive 252 is applied to the upper surface of the support 220, and the glass 210 is bonded. The semiconductor package 200 shown in FIG. 2 is obtained by the processes of FIGS. 4 to 12.

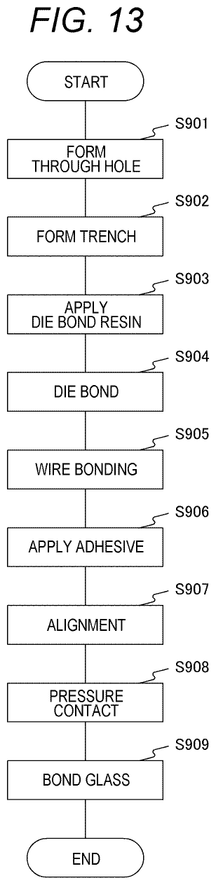

FIG. 13 is a flowchart illustrating an example of a method for manufacturing the semiconductor package 200 according to the first embodiment of the present technology. The manufacturing system of the semiconductor package 200 forms a through hole in the substrate 240 (step S901) and forms a trench (step S902). Then, the manufacturing system applies a die bond resin to the substrate 240 (step S903), and performs die bonding (step S904) and wire bonding (step S905) of the sensor chip 230.

In addition, the manufacturing system applies an adhesive to the support 220 (step S906), places the support 220 on the substrate 240 with a sensor chip, and performs alignment (step S907).

Then, the manufacturing system brings the substrate 240 with a sensor chip into pressure contact with the support 220 (step S908), bonds the glass 210 (step S909), and ends the manufacturing process.

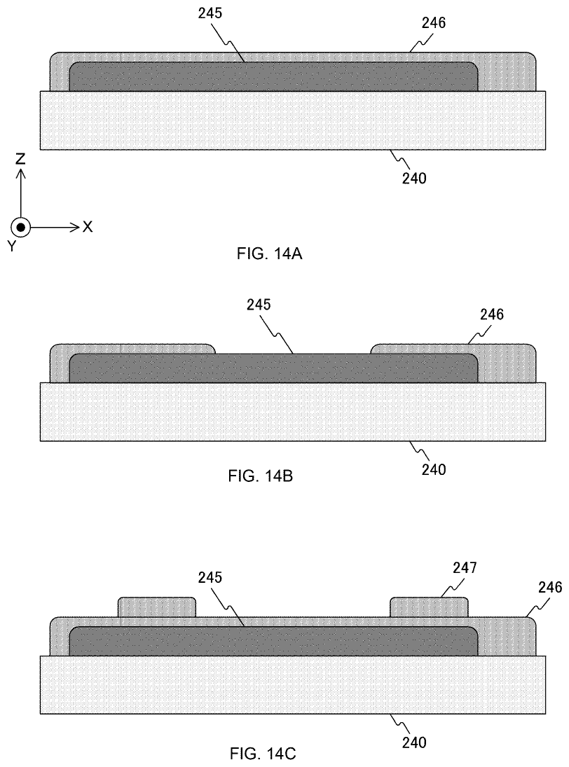

Next, a method for forming the trench 244 will be described with reference to FIGS. 14 to 16.

FIG. 14 is a view for explaining a method for forming the trench 244 with a solder resist according to the first embodiment of the present technology.

For example, as exemplified in a in the drawing, a conductor 245 is formed on the upper surface of the substrate 240, and a solder resist 246 is applied. At least a part of the conductor 245 is electrically connected and used as wiring. A part of the conductor 245 may be used as a ground.

Then, as exemplified in b in the drawing, a pattern of the solder resist 246 is formed by photolithography. Thus, the trench 244 is formed. In a case where the solder resist 246 on the wiring is patterned, a step of about 5 to 10 micrometers (μm) can be generally formed.

As described above, in the method for forming the trench 244 by the solder resist 246, it is not necessary to add a new process since the solder resist 246 is a component originally present for wiring protection and insulation of the surface of the substrate 240. In addition, since the pattern is formed by photolithography, this method has high accuracy and degree of freedom in position and shape, and is suitable for a case where a step requires a complicated shape and high accuracy.

Note that, as exemplified in c of the figure, the trench 244 can also be provided by further forming the solder resist 247 in an overlapping manner after a in the figure. As a result, it is possible to form the trench 244 without providing design restriction while avoiding exposure of the conductor 245.

In addition to the method shown in the drawing, the trench 244 can also be formed by a conductor pattern.

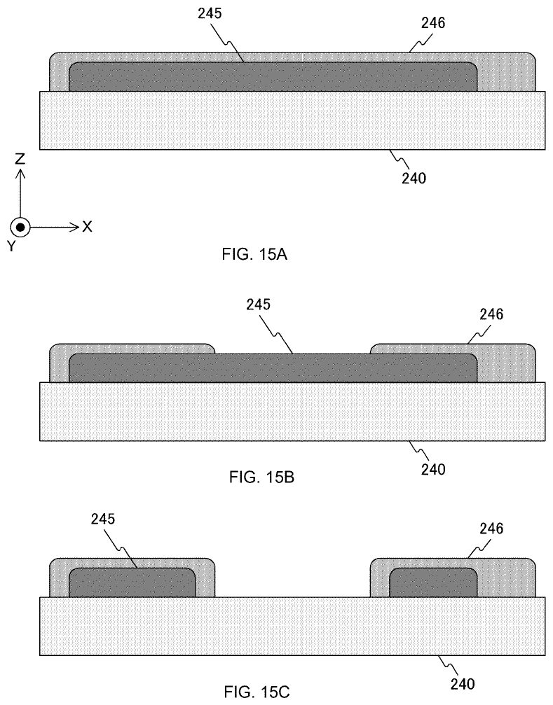

FIG. 15 is a view for explaining a method for forming the trench 244 by the conductor pattern according to the first embodiment of the present technology.

For example, as exemplified in a in the drawing, a conductor 245 is formed on the upper surface of the substrate 240, and a solder resist 246 is applied.

Then, as exemplified in b in the drawing, a pattern of the solder resist 246 is formed by photolithography.

Further, as exemplified in c in the drawing, a pattern of the conductor 245 is formed by photolithography. At least a part of the pattern of the conductor 245 is electrically connected and used as a wiring pattern. In addition, the trench 244 is formed by the pattern of the conductor 245.

As described above, in the method for forming the trench 244 by the conductor pattern, since the surface wiring is a component that originally exists, addition of a new process is unnecessary. In addition, since the pattern is formed by photolithography, this method has high accuracy and degree of freedom in position and shape, and is suitable for a case where a step requires a complicated shape and high accuracy.

In addition to the methods shown in FIGS. 14 and 15, the trench 244 can also be formed by grinding the substrate 240.

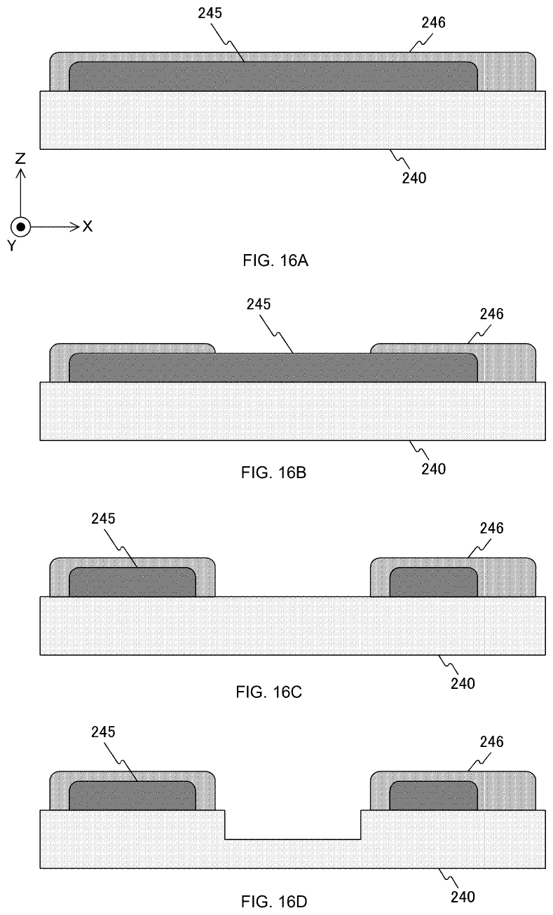

FIG. 16 is a view for explaining a method for forming the trench 244 by grinding the substrate 240 according to the first embodiment of the present technology.

For example, as exemplified in a in the drawing, a conductor 245 is formed on the upper surface of the substrate 240, and a solder resist 246 is applied.

Then, as exemplified in b in the drawing, a pattern of the solder resist 246 is formed. Further, a pattern of the conductor 245 is formed as exemplified in c in the drawing.

Subsequently, as exemplified in d in the drawing, a part of the upper surface of the substrate 240 is ground by router processing or the like to form the trench 244.

As described above, the method for forming the trench 244 by grinding the substrate 240 is suitable for the case of forming a relatively deep step such as 0.1 millimeter (mm) or more since mechanical grinding is performed.

Note that, in addition to the methods shown in FIGS. 14 to 16, the trench 244 can also be formed by silk printing.

As described above, according to the first embodiment of the present technology, since the trench 244 is formed in the substrate 240, it is possible to suppress flowing out of the adhesive 251 to the outside of the prescribed region when the substrate 240 with a sensor chip is bonded. In addition, generation of voids can also be suppressed.

### 2. Second Embodiment

In the first embodiment described above, the trench 244 is formed on the upper surface of the substrate 240 to suppress flowing out of the adhesive 251, but with this configuration, it is difficult to prevent the sensor chip 230 from being inclined. A semiconductor package 200 according to the second embodiment is different from that of the first embodiment in that a sensor chip 230 and a substrate 240 are bonded by a die bond resin containing a filler.

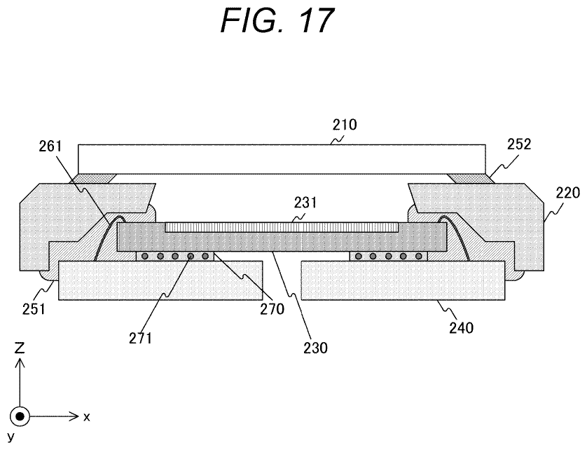

FIG. 17 is an example of a cross-sectional view of the semiconductor package 200 according to the second embodiment of the present technology. FIG. 17 is a cross-sectional view viewed from the y-axis direction. The semiconductor package 200 of the second embodiment is different from that of the first embodiment in that the trench 244 is not formed on the upper surface of the substrate 240, and a die bond resin 270 containing a filler 271 is used instead of the die bond resin 253 containing no filler.

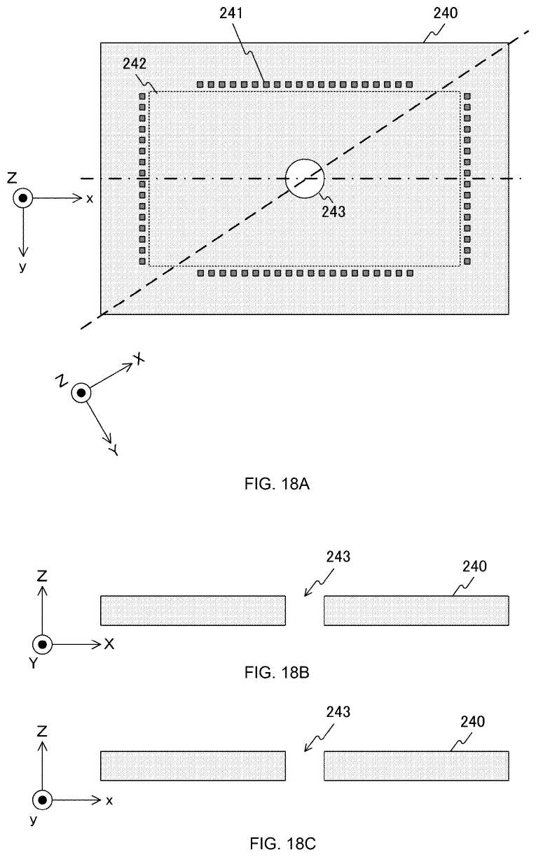

Next, a method for manufacturing the semiconductor package 200 of the second embodiment will be described with reference to FIGS. 18 to 20.

FIG. 18 is an example of a top view and a cross-sectional view of the substrate 240 in which a through hole 243 is formed according to the second embodiment of the present technology. In the drawing, a shows a top view of the substrate 240, and b shows a cross-sectional view of the substrate 240 when cut along a rough dotted line of a in the drawing. In the drawing, c illustrates a cross-sectional view of the substrate 240 when cut along the one-dot chain line of a in the drawing.

As exemplified in a, b, and c in the drawing, a through hole 243 and a terminal 241 are formed similarly to the first embodiment.

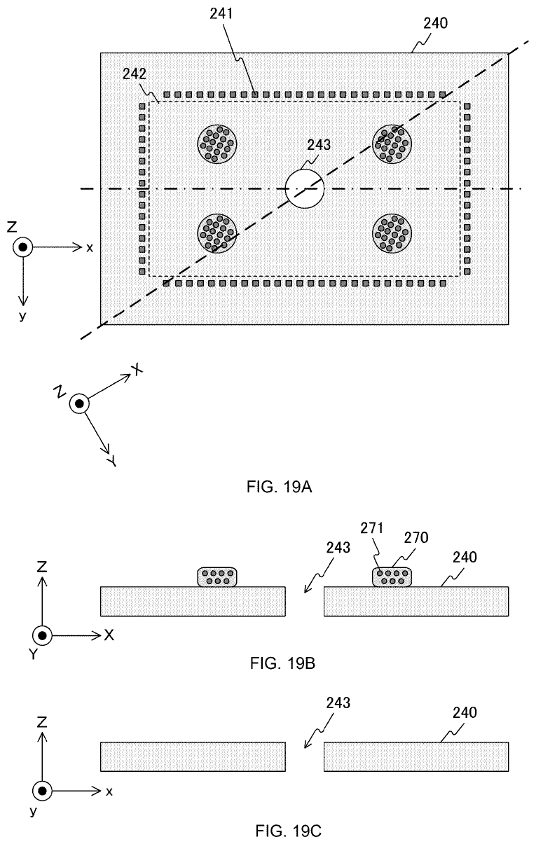

FIG. 19 is an example of a top view and a cross-sectional view of a substrate coated with the die bond resin 270 according to the second embodiment of the present technology. In the drawing, a shows a top view of the substrate 240, and b shows a cross-sectional view of the substrate 240 when cut along a rough dotted line of a in the drawing. In the drawing, c illustrates a cross-sectional view of the substrate 240 when cut along the one-dot chain line of a in the drawing.

As exemplified in a and b in the drawing, the die bond resin 270 in which the maximum diameter of the filler 271 is controlled to a predetermined size is applied in the chip mounting area 242.

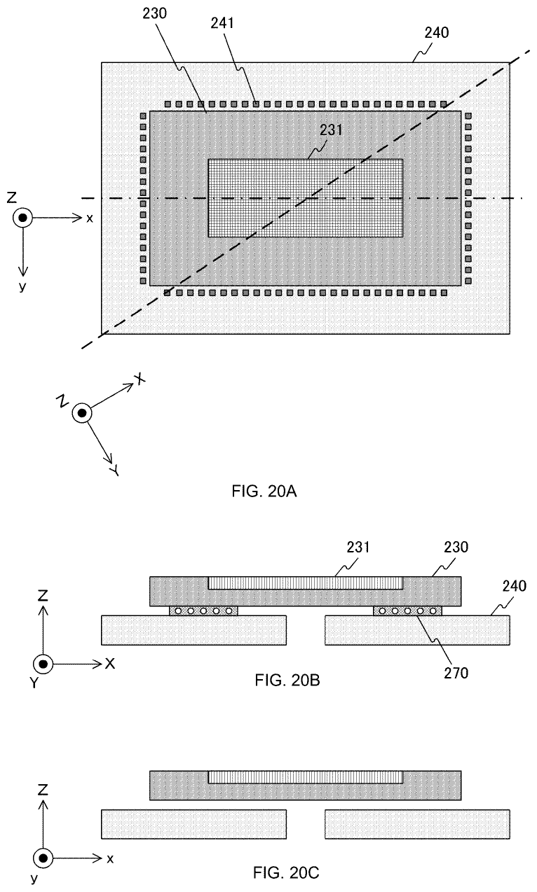

FIG. 20 is an example of a top view and a cross-sectional view of the semiconductor package 200 to which the sensor chip 230 is die-bonded according to the second embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a in the drawing, after the die bond resin 270 is applied, the sensor chip 230 is placed on the chip mounting area 242 and die-bonded. At this time, the die bond resin 270 is not crushed to a diameter less than the filler diameter by the filler 271 in the die bond resin 270. Therefore, it is possible to suppress the sensor chip 230 from being inclined in a subsequent pressure contact process. In addition, a gap equal to or larger than the filler diameter can be secured between the sensor chip 230 and the substrate 240. As a result, it is possible to suppress flowing out of the adhesive 251 to the outside of the prescribed region and generation of voids.

Also similarly to the second embodiment, after the processes shown in FIG. 20, the processes of wire bonding, application of an adhesive 251, alignment, pressure contact, and adhesion of glass are performed as in the first embodiment. Since these processes are similar to those of the first embodiment, the drawings are omitted.

As described above, according to the second embodiment of the present technology, since the sensor chip 230 and the substrate 240 are bonded by the die bond resin 270 containing the filler 271, inclination of the sensor chip 230 can be suppressed. In addition, it is possible to suppress flowing out of the adhesive 251 to the outside of the prescribed region and the generation of voids.

### 3. Third Embodiment

In the second embodiment described above, the gap is secured by the die bond resin 270 containing the filler 271, but in this configuration, it is difficult to further increase the volume of the gap. A semiconductor package 200 according to a third embodiment is different from that of the second embodiment in that a trench 244 is formed in a substrate 240.

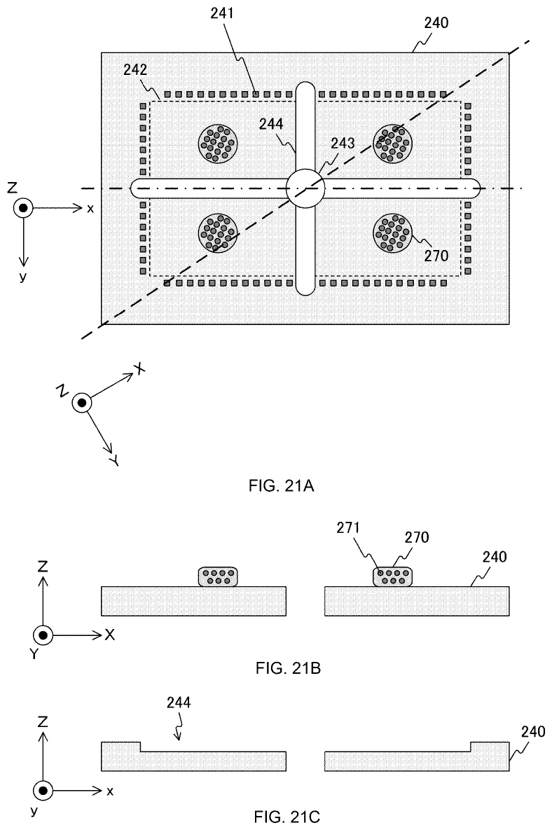

FIG. 21 is an example of a top view and a cross-sectional view of the substrate 240 according to the third embodiment of the present technology. In the drawing, a shows a top view of the substrate 240, and b shows a cross-sectional view of the substrate 240 when cut along a rough dotted line of a in the drawing. In the drawing, c illustrates a cross-sectional view of the substrate 240 when cut along the one-dot chain line of a in the drawing.

As exemplified in a in the drawing, the trench 244 is formed on the upper surface of the substrate 240. Unlike the first embodiment, the trench 244 is formed in a + shape along the x-axis direction and the y-axis direction.

By combining the trench 244 and the die bond resin 270 containing the filler 271, the volume of the gap between the sensor chip 230 and the substrate 240 can be further increased. Note that the layout and shape of the trench 244 on the substrate flat surface can be appropriately changed in consideration of the arrangement of the terminals 241, the position where the adhesive 251 easily flows out, and the like.

In addition, the depth of the trench 244 is preferably larger than the diameter of the filler 271 in the die bond resin 270.

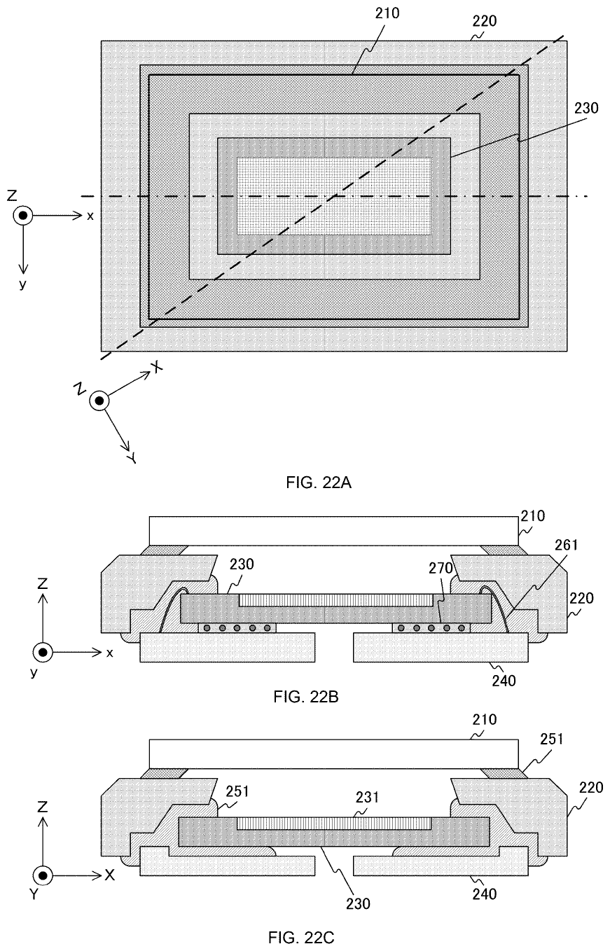

FIG. 22 is an example of a top view and a cross-sectional view of the semiconductor package 200 according to the third embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in b and c in the drawing, the trench 244 and the die bond resin 270 containing the filler 271 are provided.

As described above, according to the third embodiment of the present technology, since the trench 244 and the die bond resin 270 containing the filler 271 are used, the volume of the gap between the sensor chip 230 and the substrate 240 can be further increased.

### 4. Fourth Embodiment

In the first embodiment described above, the trench 244 suppresses flowing out of the adhesive 251 to the outside of the prescribed region, but in this configuration, the adhesive 251 may flow out to the light receiving section 231 depending on various conditions. A semiconductor package 200 according to a fourth embodiment is different from that of the first embodiment in that a projection is provided on a support 220 and a silicone resin is filled between the projection and a sensor chip 230.

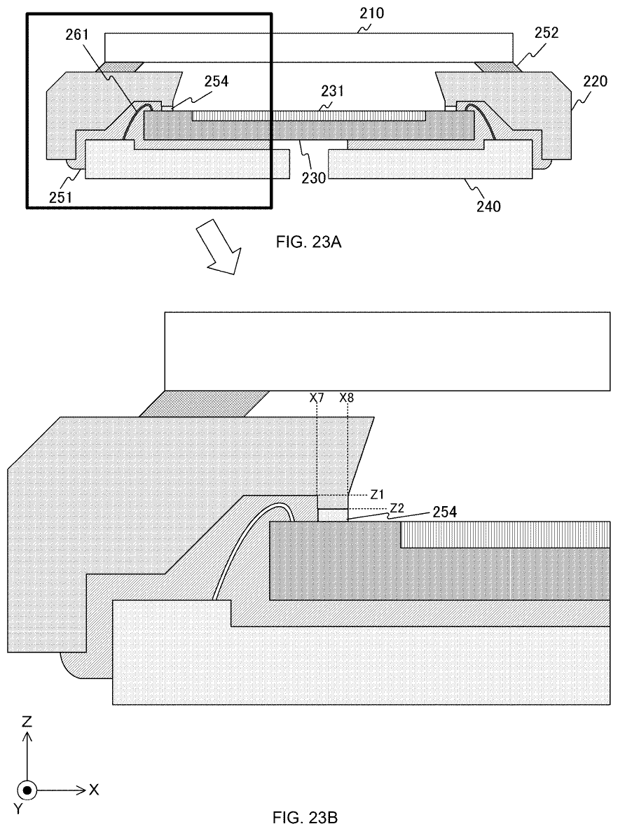

FIG. 23 is an example of a cross-sectional view and an enlarged view of the semiconductor package 200 according to the fourth embodiment of the present technology. In the figure, a shows a cross-sectional view of the semiconductor package 200, and b in the figure shows an enlarged view in which a thick frame of a in the figure is enlarged.

As exemplified in a and b in the drawing, the support 220 of the fourth embodiment is different from that of the first embodiment in that a protrusion protruding toward the sensor chip 230 is formed around the opening on the lower surface. In the drawing, coordinates X7 and X8 indicate coordinates of the left end and the right end of the protrusion, and coordinates Z1 and Z2 indicate coordinates of the upper end and the lower end of the protrusion. In addition, a silicone resin 254 is filled between the protrusion and the sensor chip 230. The protrusion and the silicone resin 254 can physically prevent flowing out of the adhesive 251 to the upper surface of the sensor chip 230. In addition, by using the silicone resin 254 for preventing flowing out, even when the resin itself comes into contact with the sensor chip 230, it is possible to prevent the chip from being damaged.

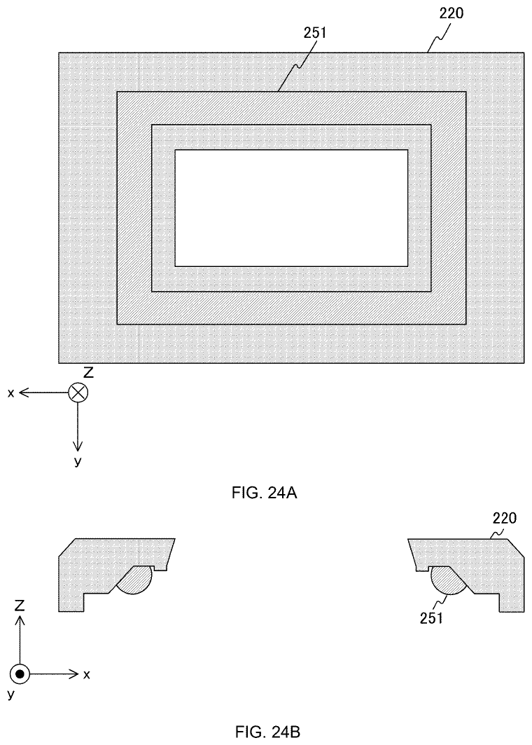

FIG. 24 is an example of a bottom view and a cross-sectional view of the support 220 to which the adhesive 251 is applied according to the fourth embodiment of the present technology. In the drawing, a shows a bottom view of the support 220, and b shows a cross-sectional view of the support 220. Also in the fourth embodiment, the adhesive 251 is applied similarly to the first embodiment.

Note that processes up to wire bonding in the fourth embodiment are similar to those in the first embodiment.

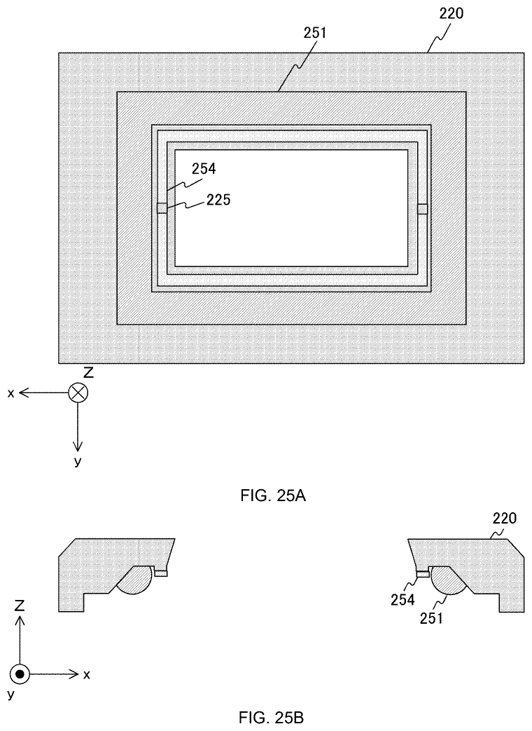

FIG. 25 is an example of a bottom view and a cross-sectional view of the support 220 coated with the silicone resin 254 according to the fourth embodiment of the present technology. In the drawing, a shows a bottom view of the support 220, and b shows a cross-sectional view of the support 220.

As exemplified in a and b in the drawing, the silicone resin 254 is applied to the projection of the support 220. Here, as exemplified in a in the drawing, the projection is formed along the side so as to surround the opening of the support 220, but there is no projection on a part of the periphery of the opening, and the silicone resin 254 is not applied, and this portion is a slit 225. When the substrate 240 is bonded, generation of voids can be suppressed by discharging gas through the slit 225 of the support 220 and a through hole 243 of a substrate 240. The slits 225 are preferably provided at two or more locations.

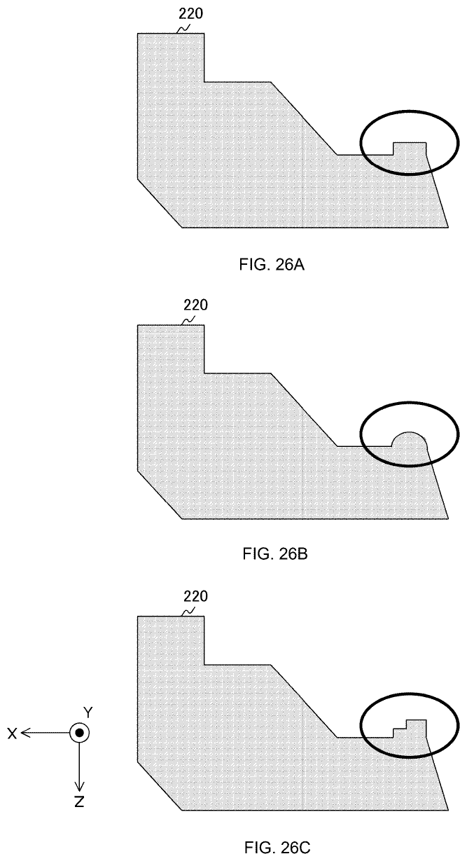

FIG. 26 is a view illustrating an example of the shape of the projection according to the fourth embodiment of the present technology. As exemplified in a in the drawing, the cross-sectional shape of the projection is, for example, rectangular.

Note that the cross-sectional shape of the projection is not limited to a rectangular shape, and may be a semi-elliptical shape as exemplified in b in the drawing. Alternatively, as exemplified in c in the drawing, the cross-sectional shape of the projection may be a stepped shape.

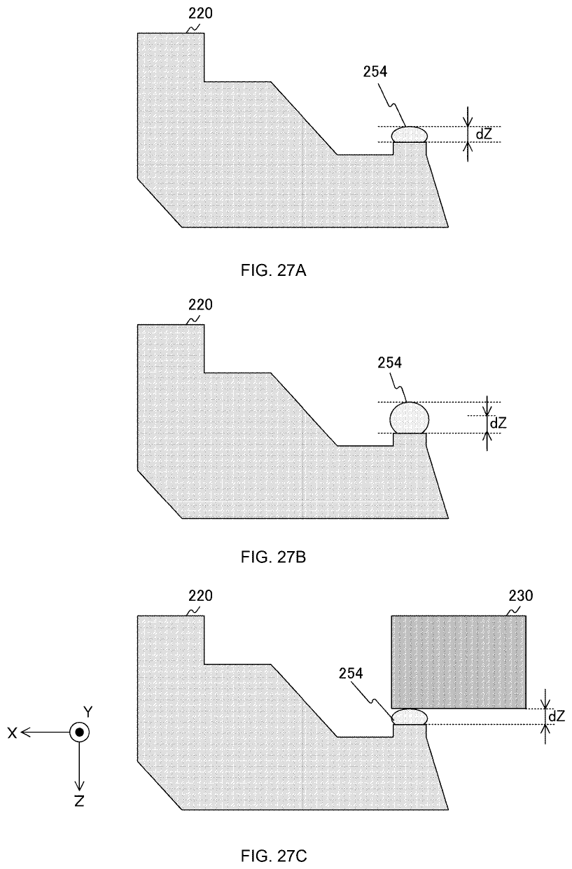

FIG. 27 is a view for explaining the method for curing the silicone resin 254 according to the fourth embodiment of the present technology. A gap between the projection and the lower surface of the sensor chip 230 at the end of curing is denoted by dZ.

As exemplified in a in the drawing, for example, the silicone resin 254 is applied at substantially the same height as dZ, and the silicone resin 254 is finally cured by ultraviolet rays, heating, a curing agent, or the like after the sensor chip 230 is placed.

Alternatively, as exemplified in b in the drawing, the silicone resin 254 higher than dZ may be applied and temporarily cured, and as exemplified in c in the drawing, the sensor chip 230 may be fully cured after being placed. For example, in a case where the silicone resin 254 is reduced during main curing, a method of curing in two stages is used.

Note that the fourth embodiment can also be applied to the second and third embodiments.

As described above, according to the fourth embodiment of the present technology, since the projection is formed in the support 220 and the silicone resin 254 is provided between the projection and the sensor chip 230, it is possible to reliably prevent flowing out of the adhesive 251 to the sensor chip 230.

### 5. Fifth Embodiment

In the first embodiment described above, the trench 244 is provided in the substrate 240 to suppress flowing out of the adhesive 251, but there is a possibility that the flow out cannot be sufficiently suppressed in a case where the amount of the adhesive 251 is more than expected. A semiconductor package 200 of a fifth embodiment is different from that of the first embodiment in that a slit is provided in a support 220.

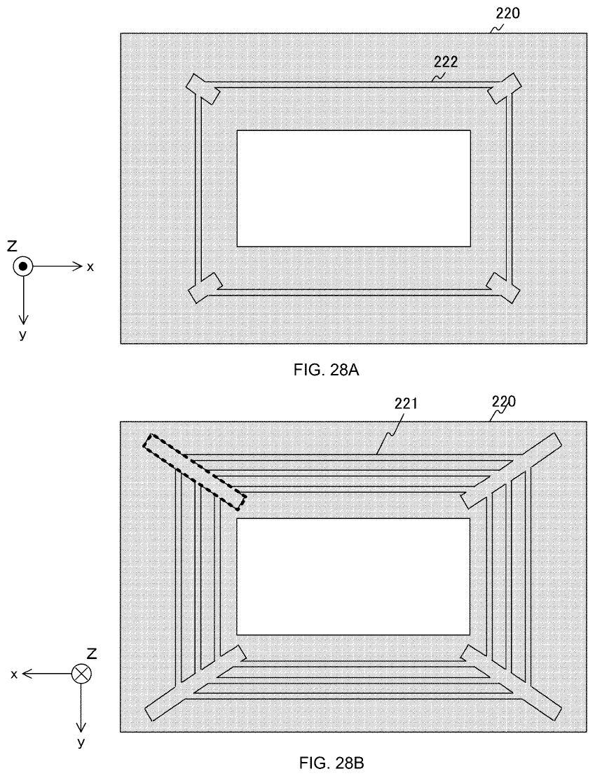

FIG. 28 is an example of a top view and a bottom view of the support 220 according to the fifth embodiment of the present technology. In the drawing, a is an example of a top view of the support 220, and b in the drawing is an example of a bottom view of the support 220.

As exemplified in a in the drawing, a support 220 of the fifth embodiment is different from that of the first embodiment in that a slit 222 is formed on the upper surface. Note that the slit 222 is an example of a second slit described in the claims.

Further, as exemplified in b in the drawing, the support 220 of the fifth embodiment is different from that of the first embodiment in that a slit 221 is formed on the lower surface. The shape of the slit 221 is a shape in which portions formed at the four corners in the oblique direction and portions formed in parallel to the sides of the support 220 are connected. A portion surrounded by a thick dotted line of b in the drawing indicates one of slit portions in an oblique direction. Note that the slit 221 is an example of a first slit described in the claims.

The shape of the slits 221 and 222 is not particularly limited, and may be any shape that can be formed by processing. By providing the slit 221 on the lower surface of the support 220, a part of the adhesive 251 wet-spread at the time of pressure contact is trapped and is not guided by the slit 221 to protrude from the support 220. In addition, by providing the slit 222 on the upper surface of the support 220, when the glass 210 is bonded to the support 220, the excessive adhesive 252 is trapped and does not protrude to an unnecessary portion.

In addition, as will be described later, a through hole may be provided in the support 220 instead of the slits 221 and 222.

In addition, the cross-sectional shapes of the slits 221 and 222 and the through hole may be, for example, straight shapes, but preferably trapezoidal shapes, and a structure in which gas generated during adhesion is discharged and extruded is preferable. As a result, generation of voids in the adhesives 251 and 252 can be suppressed.

Further, a recess having a predetermined area can be formed as a resin reservoir area in the slits 221 and 222 or a part of the through hole. As a result, when the adhesive 251 or 252 is excessive, the resin accumulation area can function as a buffer.

Further, the slits 221 and 222 do not penetrate the support 220 in a and b in the drawing, but these slits may penetrate the support 220. In addition, the number of slits is not limited as long as machining is possible.

In addition, the slits 221 and 222 are formed so as to surround the opening of the support 220 as exemplified in a and b in the drawing.

In addition, as will be described later, a through hole may be further formed in at least a part of the slit 221 and the slit 222, and these slits may be connected. As a result, even when either the upper adhesive 251 or the lower adhesive 252 is excessive, the common through hole can function as the retraction region.

In addition, since the adhesive 251 tends to accumulate at the four corners, it is possible to prevent the adhesive 251 from protruding from the four corners by forming slit portions in oblique directions at the four corners as exemplified in b in the drawing. In addition, it is possible to prevent a decrease in the strength of the support 220 due to an increase in the bonding area.

In b in the drawing, the portions of the four corners in the oblique direction and the portions parallel to the side of the support 220 are connected, but these portions may be divided as described later. In this case, the slits parallel to the sides can be arranged in a staggered manner.

In addition, processing of the slits 221 and 222 is preferably performed by a mold. However, regarding processing of fine slits, sublimation processing can also be performed directly on the support 220 with a laser or the like. In addition, the pitch between the slits and the depth of the slits can be made fine as long as they can be processed.

In addition, in order to reduce the risk of void generation at the time of bonding the support 220, it is preferable to perform pressure bonding under vacuum conditions.

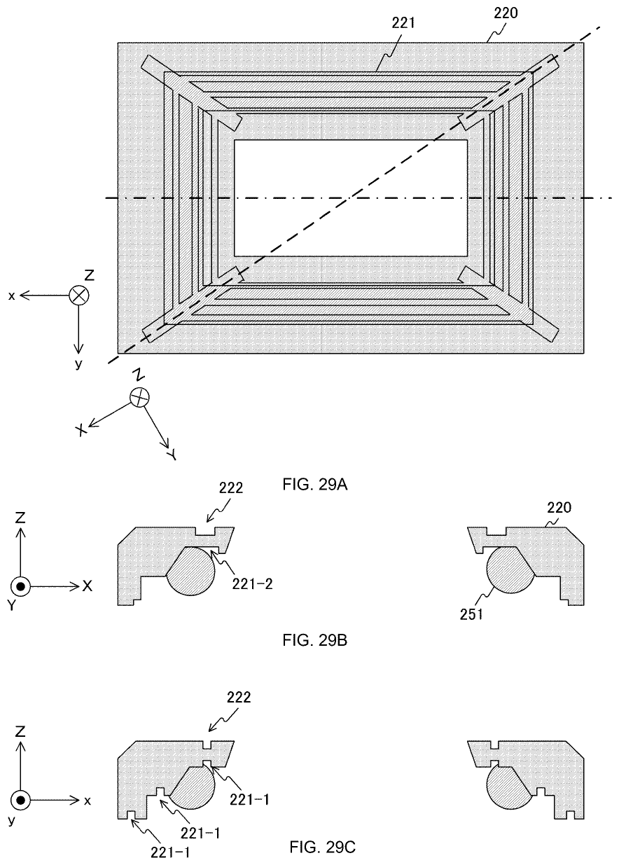

FIG. 29 is an example of a bottom view and a cross-sectional view of the support 220 to which the adhesive 251 is applied according to the fifth embodiment of the present technology. In the drawing, a shows a bottom view of the support 220, and b shows a cross-sectional view of the support 220 when cut along a rough dotted line of a in the drawing. In the drawing, c shows a cross-sectional view of the support 220 when cut along the one-dot chain line of a in the drawing.

As exemplified in b in the drawing, slits in oblique directions are formed at four corners, and these portions are referred to as slit portions 221-2.

As exemplified in c in the drawing, slits are formed in parallel to the sides, and these portions are referred to as slit portions 221-1. As exemplified in the bottom view in a in the drawing, the slit portion 221-1 and the slit portion 221-2 are connected.

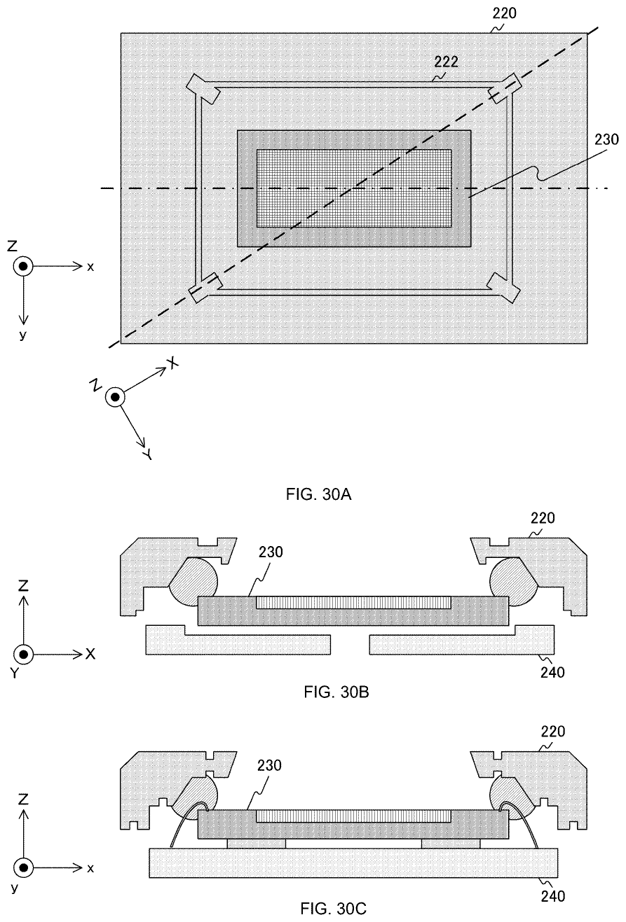

FIG. 30 is an example of a top view and a cross-sectional view of the semiconductor package 200 on which the support 220 is placed according to the fifth embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a, b, and c in the drawing, after the adhesive 251 is applied, the support 220 is placed on the substrate 240 with a sensor chip.

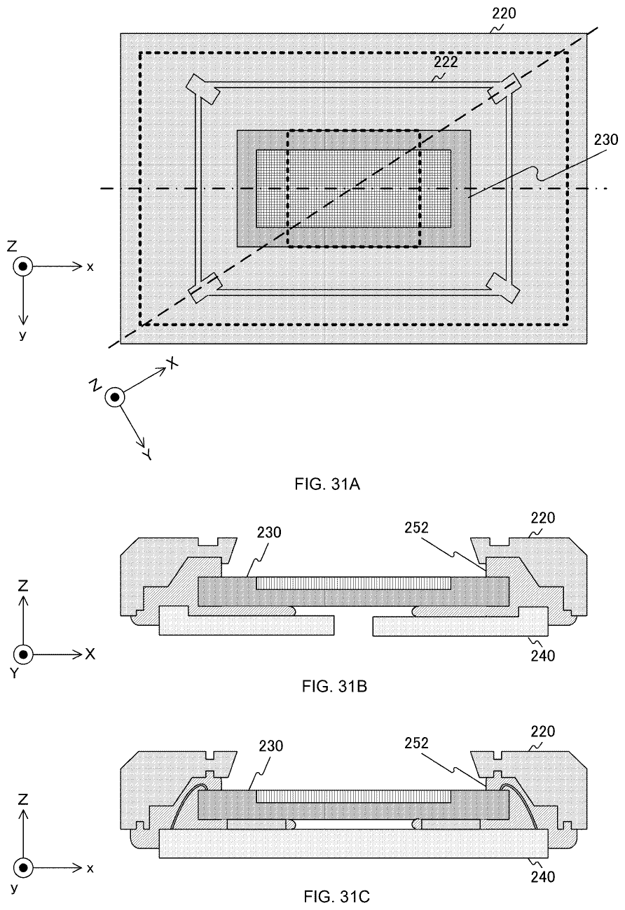

FIG. 31 is an example of a top view and a cross-sectional view of the semiconductor package 200 in which the substrate 240 is brought into pressure contact according to the fifth embodiment of the present technology. In the drawing, a shows a top view of the semiconductor package 200, and b shows a cross-sectional view of the semiconductor package 200 when cut along a rough dotted line of a in the drawing. In the drawing, c illustrates a cross-sectional view of the semiconductor package 200 when cut along the one-dot chain line of a in the drawing.

As exemplified in a, b, and c in the drawing, the substrate 240 with a sensor chip is brought into pressure contact with the support 220 after the alignment. At this time, the adhesive 252 crushed and flowing flows into the trench 244, and further flows into the slit 221 on the lower surface of the support 220. Therefore, flowing out of the adhesive 251 to unnecessary portions is prevented.

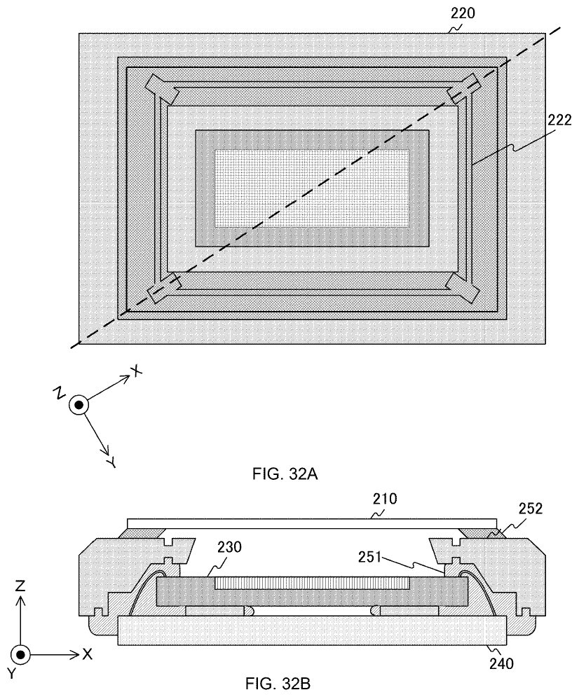

FIG. 32 is an example of a top view and a cross-sectional view of the semiconductor package 200 to which the glass 210 is bonded according to the fifth embodiment of the present technology. In the drawing, a shows a top view of the semiconductor package 200, and b shows a cross-sectional view of the semiconductor package 200 when cut along a rough dotted line of a in the drawing.

As exemplified in a and b in the drawing, after pressure contact of the substrate 240 with a sensor chip, the adhesive 252 is applied to the upper surface of the support 220, and the glass 210 is bonded. At this time, since a part of the adhesive 252 flows into the slit 222 on the upper surface of the support 220, it is possible to suppress flowing out of the adhesive 252 to unnecessary portions.

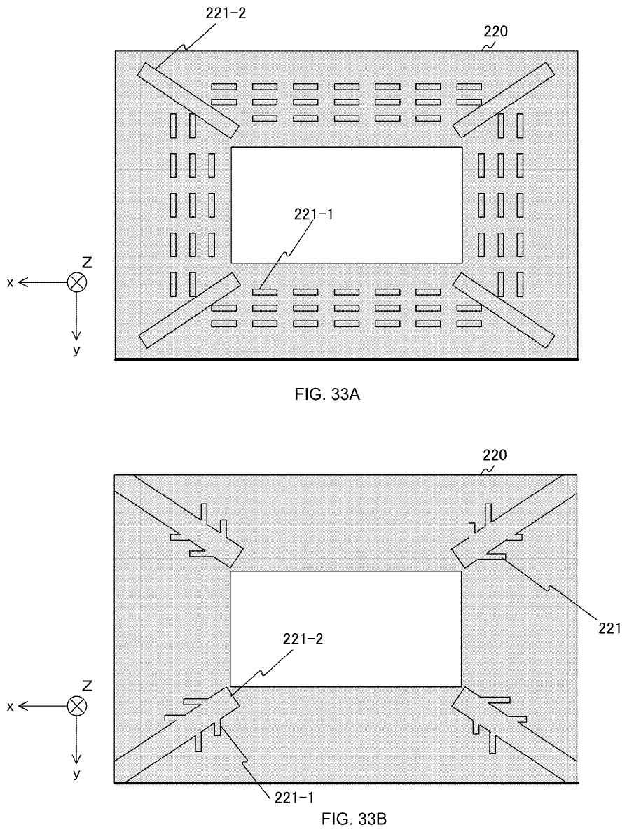

FIG. 33 is a plan view illustrating another pattern of the slits 221 on the lower surface of the support 220 according to the fifth embodiment of the present technology.

As exemplified in a in the drawing, the slit portions 221-1 parallel to the side and the slit portions 221-2 in the oblique direction can be divided. At this time, the slit portions 221-1 can be arranged in a staggered arrangement.

Alternatively, as exemplified in b in the drawing, the slit portion 221-1 perpendicular to the side can be formed.

Regarding the difference between a and b in the drawing, attention is paid to the side of the region between the adjacent two slit portions 221-2 in the oblique direction. Thick lines a and b in the drawing indicate the focused sides. In a in the drawing, the slit portion 221-2 between the adjacent two slit portions 221-1 in the oblique direction is formed in parallel to the side of interest, but in b in the drawing, the slit portion is formed perpendicular to the side of interest.

Note that, in b in the drawing, the slit portion 221-1 and the slit portion 221-2 can be divided.

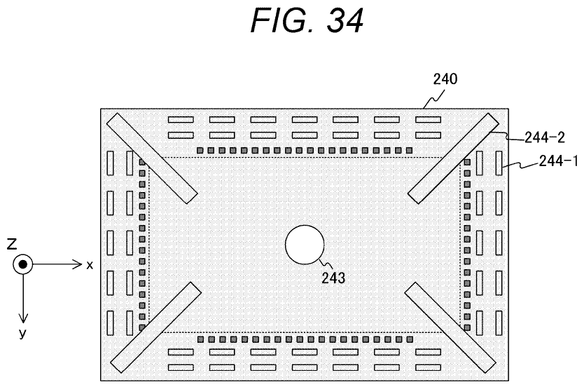

FIG. 34 is a plan view illustrating a pattern of trenches on the upper surface of the substrate according to the fifth embodiment of the present technology. In addition to the trench in the oblique direction in the first embodiment, trenches parallel to the sides of the substrate 240 can be further formed. A portion parallel to the side is defined as a trench portion 244-1, and a portion in an oblique direction is defined as a trench portion 244-2.

Note that the fifth embodiment can also be applied to each of the second, third, and fourth embodiments.

As described above, according to the fifth embodiment of the present technology, since the slits 221 and 222 are formed in the support 220, it is possible to prevent the adhesives 251 and 252 from flowing out.

### Modifications

In the above-described fifth embodiment, the slits 221 and 222 are formed in the support 220. However, in a case where the amount of the adhesives 251 and 252 is more than expected, there is a possibility that the flow out cannot be sufficiently suppressed. A semiconductor package 200 according to a modification of the fifth embodiment is different from that of the fifth embodiment in that a through hole is formed in a support 220.

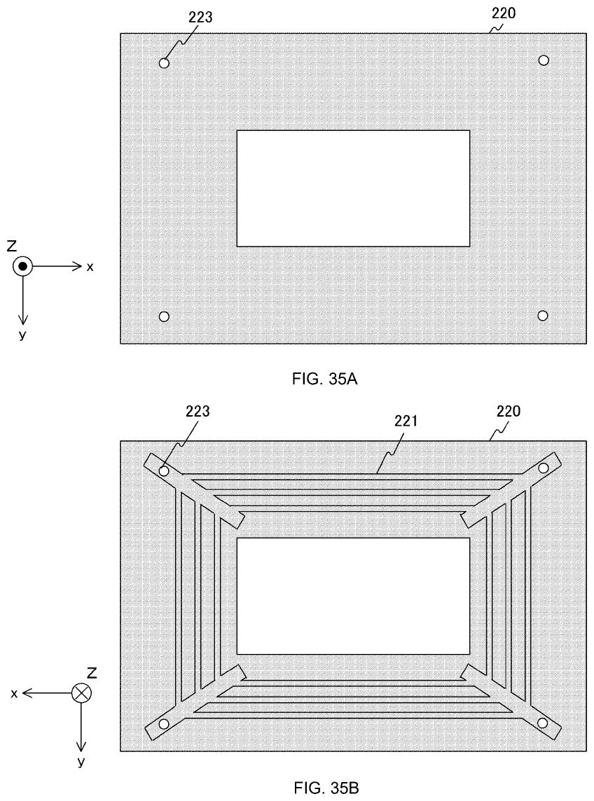

FIG. 35 is an example of a top view and a bottom view of the support 220 according to the modification of the fifth embodiment of the present technology. In the drawing, a is an example of a top view of the support 220, and b in the drawing is an example of a bottom view of the support 220.

As exemplified in a in the drawing, in the modification of the fifth embodiment, the slit 222 is not formed on the upper surface of the support 220. In addition, as exemplified in a and b in the drawing, through holes 223 are formed in the vicinities of four corners of the support 220. By forming the through holes 223, it is possible to prevent the adhesives 251 and 252 from flowing out.

Note that a slit 222 may be further formed on the upper surface of the support 220, and the slit 221 on the lower surface and the through hole 223 may be connected.

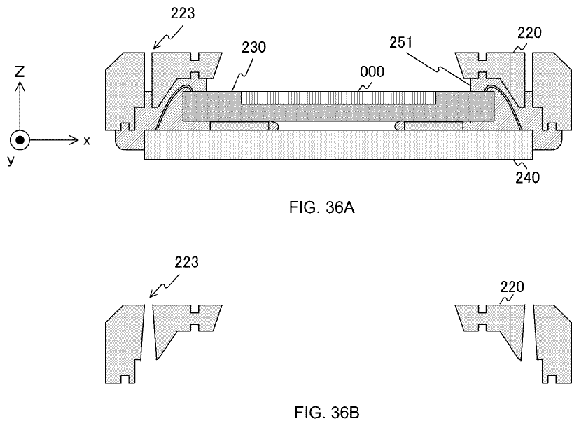

FIG. 36 is an example of a cross-sectional view of a semiconductor package 200 according to a modification of the fifth embodiment of the present technology. In the drawing, a is an example of a cross-sectional view of the semiconductor package 200 when bonded with the adhesive 251. As exemplified in a in the drawing, the cross-sectional shape of the through hole 223 is, for example, a straight shape.

Note that, as exemplified in b in the drawing, the cross-sectional shape of the through hole 223 may be trapezoidal so that the adhesive 251 can be easily pushed out.

As described above, according to the modification of the fifth embodiment of the present technology, since the through holes 223 are formed in the support 220, the adhesives 251 and 252 can be guided to the through holes 223 to prevent the adhesives 251 and 252 from flowing out.

### 6. Example of Application to Mobile Body

The technology according to the present disclosure (the present technology) can be applied to various products. For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

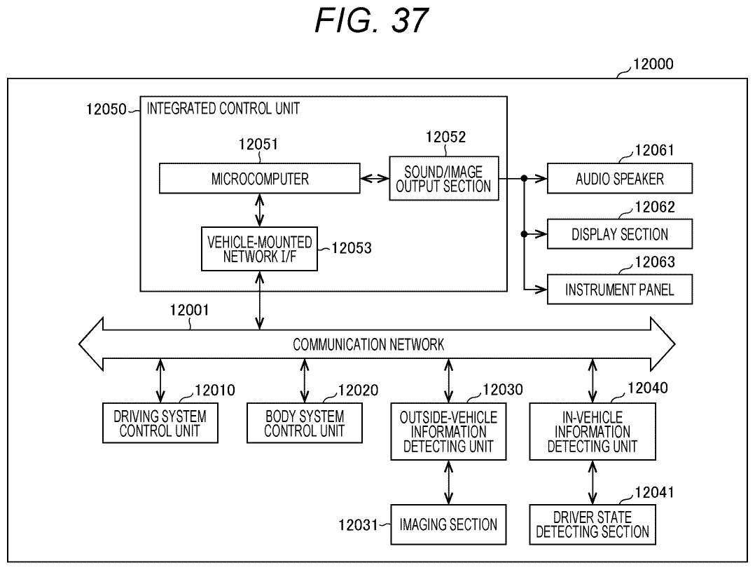

FIG. 37 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example shown in FIG. 37, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 37, an audio speaker 12061, a display section 12062, and an instrument panel 12063 are exemplified as output devices. The display section 12062 may, for example, include at least one of an on-board display and a head-up display.

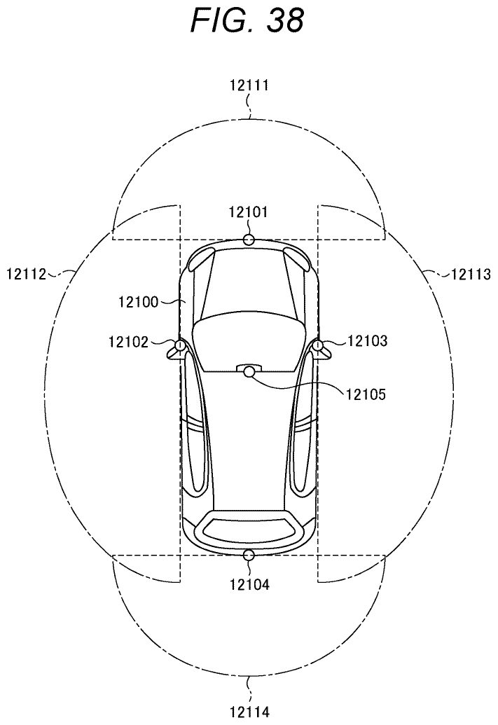

FIG. 38 is a view illustrating an example of an installation position of the imaging section 12031.

In FIG. 38, as the imaging section 12031, imaging sections 12101, 12102, 12103, 12104, and 12105 are included.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided on the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 38 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is applicable to the imaging section 12031, for example, among the configurations described above. Specifically, for example, the electronic device 100 in FIG. 1 can be applied to the imaging section 12031. By applying the technology according to the present disclosure to the imaging section 12031, it is possible to suppress flowing out of the adhesive to the outside of the prescribed region and to suppress an adverse effect on the system due to the flowing out of the adhesive.

Note that the embodiments described above show examples for embodying the present technology, and the respective matters in the embodiments and the respective matters specifying the invention in the claims have correspondence relationships. Similarly, the matters specifying the invention in the claims and the matters with the same names in the embodiments of the present technology have correspondence relationships. However, the present technology is not limited to the embodiments, and can be embodied by making various modifications to the embodiments without departing from the scope of the present technology.

Note that, the effects described in the present specification are merely examples and are not limited, and other effects may also be achieved.

Note that the present technology may also have the following configurations.

(1) A semiconductor package including:
a substrate;
a semiconductor chip placed on a substrate flat surface of the substrate and electrically connected to the substrate;
a support; and
a first adhesive partially flowing into a gap between the substrate flat surface and the semiconductor chip to bond the substrate to the support.

(2) The semiconductor package according to (1), in which
a trench is formed on the substrate flat surface.

(3) The semiconductor package according to (2), in which
the trench is formed on a base material of the substrate.

(4) The semiconductor package according to (2), in which
the trench is formed by a solder resist.

(5) The semiconductor package according to (2), in which
the trench includes a conductor pattern.

(6) The semiconductor package according to (2), in which
the trench is formed by silk printing.

(7) The semiconductor package according to any one of (1) to (6), further including
a die bond resin that contains a filler and bonds the semiconductor chip to the substrate flat surface.

(8) The semiconductor package according to any one of (1) to (7), further including:
a second adhesive; and
glass, in which
one of both surfaces of the support is bonded to the substrate with the first adhesive, and the other surface is bonded to the glass with the second adhesive.

(9) The semiconductor package according to (8), further including
a silicone resin, in which
the support has an opening,
a projection protruding toward the semiconductor chip is formed around the opening on the one of both surfaces of the support, and
the silicone resin is provided between the projection and the semiconductor chip.

(10) The semiconductor package according to (8) or (9), in which
a first slit is formed on the one of both surfaces of the support.

(11) The semiconductor package according to (10), in which the first slit includes:
a plurality of first slit portions parallel or perpendicular to a side of the support; and
a plurality of second slit portions formed in an oblique direction.

(12) The semiconductor package according to any one of (8) to (11), in which
a second slit is formed on the other of both surfaces of the support.

(13) The semiconductor package according to any one of (8) to (12), in which
a through hole is formed in the support.

(14) An electronic device including:
a substrate;
a semiconductor chip placed on a substrate flat surface of the substrate and electrically connected to the substrate;
a support;
a first adhesive partially flowing into a gap between the substrate flat surface and the semiconductor chip to bond the substrate to the support; and
an optical section that guides light to the semiconductor chip.

### REFERENCE SIGNS LIST

100 Electronic device
110 Optical section
120 DSP circuit
130 Display section
140 Operation section
150 Bus
160 Frame memory
170 Storage section
180 Power supply section
200 Semiconductor package
210 Glass
220 Support
221, 222, 225 Slit
221-1, 221-2 Slit portion
223, 243 Through hole
230 Sensor chip
231 Light receiving section
240 Substrate
241 Terminal
242 Chip mounting area
244 Trench
244-1, 244-2 Trench portion
245 Conductor
246, 247 Solder resist
251, 252 Adhesive
253, 270 Die bond resin
254 Silicone resin
261 Wire
271 Filler
12031 Imaging section

1. A semiconductor package comprising:
a substrate;
a semiconductor chip placed on a substrate flat surface of the substrate and electrically connected to the substrate;
a support; and
a first adhesive partially flowing into a gap between the substrate flat surface and the semiconductor chip to bond the substrate to the support.

2. The semiconductor package according to claim 1, wherein
a trench is formed on the substrate flat surface.

3. The semiconductor package according to claim 2, wherein
the trench is formed on a base material of the substrate.

4. The semiconductor package according to claim 2, wherein
the trench is formed by a solder resist.

5. The semiconductor package according to claim 2, wherein
the trench includes a conductor pattern.

6. The semiconductor package according to claim 2, wherein
the trench is formed by silk printing.

7. The semiconductor package according to claim 1, further comprising
a die bond resin that contains a filler and bonds the semiconductor chip to the substrate flat surface.

8. The semiconductor package according to claim 1, further comprising:
a second adhesive; and
glass, wherein
one of both surfaces of the support is bonded to the substrate with the first adhesive, and the other surface is bonded to the glass with the second adhesive.

9. The semiconductor package according to claim 8, further comprising
a silicone resin, wherein
the support has an opening,
a projection protruding toward the semiconductor chip is formed around the opening on the one of both surfaces of the support, and
the silicone resin is provided between the projection and the semiconductor chip.

10. The semiconductor package according to claim 8, wherein
a first slit is formed on the one of both surfaces of the support.

11. The semiconductor package according to claim 10, wherein the first slit includes:
a plurality of first slit portions parallel or perpendicular to a side of the support; and
a plurality of second slit portions formed in an oblique direction.

12. The semiconductor package according to claim 8, wherein
a second slit is formed on the other of both surfaces of the support.

13. The semiconductor package according to claim 8, wherein
a through hole is formed in the support.

14. An electronic device comprising:
a substrate;
a semiconductor chip placed on a substrate flat surface of the substrate and electrically connected to the substrate;
a support;
a first adhesive partially flowing into a gap between the substrate flat surface and the semiconductor chip to bond the substrate to the support; and
an optical section that guides light to the semiconductor chip.
